(19) United States
(12) Patent Application Publication
(10) Pub. No.: US 2025/0095955 A1
(43) Pub. Date: Mar. 20, 2025

(54) METHOD AND SYSTEM FOR CALIBRATION OF DIFFRACTION ANGLES

(71) Applicant: Applied Materials Israel Ltd., Rehovot (IL)

(72) Inventors: Konstantin Chirko, Rehovot (IL); Itamar Shani, Mishmar David (IL); Lior Yaron, Ness Ziona (IL); Guy Eytan, Kfar-Aviv (IL)

(73) Assignee: Applied Materials Israel Ltd., Rehovot (IL)

(21) Appl. No.: 18/370,303

(22) Filed: Sep. 19, 2023

(51) Int. Cl. H01J 37/26; G01N 23/203; G01N 23/2251; H01J 37/22; H01J 37/244; H01J 37/28

(52) U.S. Cl. CPC H01J 37/265; G01N 23/203; G01N 23/2251; H01J 37/222; H01J 37/28; G01N 2223/0566; G01N 2223/401; H01J 37/244; H01J 2237/2817

(57) ABSTRACT

Disclosed are method and system for calibrating a tilt angle of an electron beam of a backscattered scanning electron microscope including scanning a bare wafer at a plurality of electron beam tilt and azimuth angles, thereby obtaining a calibration map representing a crystal orientation of the bare wafer, selecting a tilt angle and defining an expected diffraction pattern associated with the tilt angle, based on the calibration map; scanning a patterned wafer at the selected tilt angle, comparing the diffraction pattern of the image obtained from the scanning of the patterned wafer at the selected tilt angle with the expected diffraction pattern; correcting the tilt angle of the electron beam of the BSEM tool, such that the diffraction pattern of the image obtained during scanning of the patterned wafer will align with the expected diffraction pattern.

### TECHNOLOGICAL FIELD

This disclosure generally relates to method and system for calibration of scanning electron microscope (SEM) tilt angles, specifically for calibration of scanning electron microscope (SEM) tilt angles based on electron channeling patterns.

### BACKGROUND OF THE INVENTION

When imaging patterned wafers based on single-crystal substrate (e.g., silicon) with back scattered electrons (BSE), depending on the angle of the tilted beams, electron diffraction contributes to the image contrast. Accordingly, the image contrast resulting from diffraction adds to the material contrast of the image and thus the shape of the pattern waveform. Due to the high sensitivity to changes in tilt angle reproducing a same diffraction effect in different wafers is challenging.

There therefore remains a need for a method and system that can predict diffraction pattern as a function of tilt angle, in order to enable reliable metrology of the pattern features of patterned wafers.

### BRIEF SUMMARY OF THE INVENTION

The present disclosure is directed to a method and system for calibration of SEM electron diffraction angles by measuring a crystal orientation of a bare (un-patterned) wafer at an accuracy exceeding 0.1 degrees and subsequently calibrating a tilt angle of a SEM scanning beam relative to the measured crystal orientation.

Advantageously, the herein disclosed method and system enables a reliable comparison of BSE images between two wafer samples, while counterbalancing the contribution of diffraction to image contrast.

As a further advantage, by deciphering the diffraction level as a function of tilt angle for a bare wafer, a reference set of contrast tilts can be derived and used for subsequent scanning of patterned wafers having a same crystal structure, thus obviating the need for repeated scanning of reference samples.

In addition, the herein disclosed method and system allows calibration of a tilt angle of a scanning beam relative to an inherent crystal orientation, thereby ensuring a scanning accuracy exceeding 0.1 degrees.

According to some embodiments, there is provided a method for calibrating a tilt angle of an electron beam of a backscattered scanning electron (BSE) tool, the method including the following steps:
a) scanning a bare wafer, such as but not limited to a bare silicon wafer, utilizing the BSE tool, at a plurality of electron beam tilt and azimuth angles, such that each image obtained spans a different tilt angle or range thereof (e.g., 2 degrees per image) at a predetermined range of azimuth angles (e.g., from 0 to 2 degrees), thereby obtaining a calibration map representing a crystal orientation of the bare wafer;
b) selecting a tilt angle and defining an expected diffraction pattern associated with the tilt angle, based on the calibration map;
c) scanning a patterned wafer at the selected tilt angle, utilizing the BSE tool, wherein the patterned wafer is of a same material as the bare wafer (e.g., silicon);
d) comparing the diffraction pattern of the image obtained from the scanning of the patterned wafer at the selected tilt angle with the expected diffraction pattern; and
e) correcting the tilt angle of the electron beam of the BSE tool, such that the diffraction pattern of the image obtained during scanning of the patterned wafer will align with the expected diffraction pattern.

According to some embodiments, the method further includes a step f) of scanning one or more additional patterned wafers at the corrected tilt angle.

As used herein, the term wafers “wafer”, “slice” and “substrate” may be used interchangeably and refer to a thin slice of semiconductor, such as crystalline silicon (c-Si) used for fabrication of integrated circuits and/or solar cells.

According to some embodiments, the term “selecting” refers to choosing a tilt angle used to obtain the expected diffraction pattern. According to some embodiments, the selecting includes selecting a tilt angle providing an optimal image contrast.

As used herein the term “expected diffraction pattern” refers to a diffraction pattern that is repeatedly obtained when scanning bare wafers (of a same material) at a selected tilt angle.

According to some embodiments, the plurality of tilt angle varies by approximately 1 degree, between scans.

According to some embodiments, the predetermined range of azimuth angles is approximately 2 degrees.

According to some embodiments, the tilt angle range around the desired tilt angle is the selected tilt angle±about 2-5 degrees.

According to some embodiments, the aligning includes superimposing the image obtained during scanning of the patterned wafer at the selected tilt angle on the image obtained during scanning of the bare wafer, such that the diffraction pattern obtained during scanning of the patterned wafer aligns with the expected diffraction pattern.

According to some embodiments, the method further includes conducting a metrology analysis of the obtained patterned wafer images.

According to some embodiments, the calibration map is a Kikuchi map.

According to some embodiments, there is provided a method for improved scanning of a patterned wafer using a backscattered scanning electron microscope (BSE) tool, the method including the following steps:
a. scanning a patterned wafer at a selected tilt angle, thereby obtaining a diffraction pattern;
b. comparing the diffraction pattern with an image having an expected diffraction pattern; wherein the expected diffraction pattern is a diffraction pattern obtained when scanning a bare wafer at the selected tilt angle; and
c. correcting the tilt angle of the electron beam of the BSEM tool, such that the diffraction pattern of the image obtained during scanning of the patterned wafer aligns with the expected diffraction pattern.

According to some embodiments, the method further includes a step d) of scanning one or more additional patterned wafers at the corrected tilt angle.

According to some embodiments, the aligning includes superimposing the image, obtained during scanning of the patterned wafer at the selected tilt angle, on the image obtained during scanning of the bare wafer, such that the diffraction pattern obtained during scanning of the patterned wafer aligns with the expected diffraction pattern.

According to some embodiments, the method further includes conducting a metrology analysis of the obtained patterned wafer images.

According to some embodiments, there is provided a system for calibrating a tilt angle of a backscattered electron beam for optimization of diffraction angles, the system comprising:
a BSE tool configured to:
   a. scan a bare wafer at a plurality of electron beam tilt angles and azimuth angles, thereby obtaining a plurality of images, each spanning a different tilt angle or range thereof at a predetermined range of azimuth angles, and
   b. scan a patterned wafer, utilizing the BSEM tool, at selected tilt angle range; and a processing unit configured to:
   a. receive the plurality of images obtained during scanning of the bare wafer;
   b. generate a calibration map representing the crystal structure of the bare wafer;
   c. select a tilt angle and defining an expected diffraction pattern associated with the tilt angle, based on the calibration map;
   d. obtain the image from the scanning of the patterned wafer at the selected tilt angle;
   e. comparing the diffraction pattern of the image of the patterned wafer with the expected diffraction pattern;
   f. determining a corrected tilt angle suitable for scanning the patterned wafer, wherein the determining comprises aligning the diffraction pattern of the patterned wafer with the expected diffraction pattern, and
   g. instructing the BSE tool to change the tilt angle of the electron beam to the corrected tilt angle.

According to some embodiments, the BSE tool is further configured to scan additional patterned wafers at the corrected tilt angle.

According to some embodiments, the processing unit is further configured to conduct a metrology analysis of the additional patterned wafers, based on the scans thereof at the corrected tilt angle.

Certain embodiments of the present disclosure may include some, all, or none of the above advantages. One or more other technical advantages may be readily apparent to those skilled in the art from the figures, descriptions, and claims included herein. Moreover, while specific advantages have been enumerated above, various embodiments may include all, some, or none of the enumerated advantages.

Unless otherwise defined, all technical and scientific terms used herein have the same meaning as commonly understood by one of ordinary skill in the art to which this disclosure pertains. In case of conflict, the patent specification, including definitions, governs. As used herein, the indefinite articles “a” and “an” mean “at least one” or “one or more” unless the context clearly dictates otherwise.

Unless specifically stated otherwise, as apparent from the disclosure, it is appreciated that, according to some embodiments, terms such as “processing”, “computing”, “calculating”, “determining”, “estimating”, “assessing”, “gauging” or the like, may refer to the action and/or processes of a computer or computing system, or similar electronic computing device, that manipulate and/or transform data, represented as physical (e.g. electronic) quantities within the computing system's registers and/or memories, into other data similarly represented as physical quantities within the computing system's memories, registers or other such information storage, transmission or display devices.

Embodiments of the present disclosure may include apparatuses for performing the operations herein. The apparatuses may be specially constructed for the desired purposes or may include a general-purpose computer(s) selectively activated or reconfigured by a computer program stored in the computer. Such a computer program may be stored in a computer readable storage medium, such as, but not limited to, any type of disk including floppy disks, optical disks, CD-ROMs, magnetic-optical disks, read-only memories (ROMs), random access memories (RAMs), electrically programmable read-only memories (EPROMs), electrically erasable and programmable read only memories (EEPROMs), magnetic or optical cards, flash memories, solid state drives (SSDs), or any other type of media suitable for storing electronic instructions, and capable of being coupled to a computer system bus.

The processes and displays presented herein are not inherently related to any particular computer or other apparatus. Various general-purpose systems may be used with programs in accordance with the teachings herein, or it may prove convenient to construct a more specialized apparatus to perform the desired method(s). The desired structure(s) for a variety of these systems appear from the description below. In addition, embodiments of the present disclosure are not described with reference to any particular programming language. It will be appreciated that a variety of programming languages may be used to implement the teachings of the present disclosure as described herein.

Aspects of the disclosure may be described in the general context of computer-executable instructions, such as program modules, being executed by a computer. Generally, program modules include routines, programs, objects, components, data structures, and so forth, which perform particular tasks or implement particular abstract data types. Disclosed embodiments may also be practiced in distributed computing environments where tasks are performed by remote processing devices that are linked through a communications network. In a distributed computing environment, program modules may be located in both local and remote computer storage media including memory storage devices.

### BRIEF DESCRIPTION OF THE DRAWINGS

Some embodiments of the disclosure are described herein with reference to the accompanying figures. The description, together with the figures, makes apparent to a person having ordinary skill in the art how some embodiments may be practiced. The figures are for the purpose of illustrative description and no attempt is made to show structural details of an embodiment in more detail than is necessary for a fundamental understanding of the disclosure. For the sake of clarity, some objects depicted in the figures are not drawn to scale. Moreover, two different objects in the same figure may be drawn to different scales. In particular, the scale of some objects may be greatly exaggerated as compared to other objects in the same figure.

In the figures:

FIG. 1 is a flowchart of the herein disclosed method for calibration of BSEM electron beam angles, according to some embodiments;

FIG. 2 shows an exemplary Kikuchi lines map at a full range of tilts obtained for an exemplary bare silicon wafer;

FIG. 3A shows a section of the images of FIG. 1 obtained when scanning the bare wafer at a range around a selected tilt angle, where the cross (in red) indicates the exact position of the selected tilt angle;

FIG. 3B shows the diffraction pattern obtained when scanning a patterned wafer at the selected tilt angle, where the blue cross indicates the exact position of the selected tilt angle and the red cross the image alignment to the red cross in FIG. 2A;

FIG. 4, depicts a computerized system for calibration of tilt angles; according to some embodiments;

FIG. 5A schematically illustrates a cross-sectional sideview of a wafer being impinged by an e-beam at a tilt angle θ₁; according to some embodiments;

FIG. 5B schematically illustrates a cross-sectional sideview of a wafer being impinged by an e-beam at a tilt angle θ₂; according to some embodiments; and

FIG. 5C schematically illustrates a cross-sectional sideview of a wafer being impinged by an e-beam at a tilt angle θ₃; according to some embodiments.

### DETAILED DESCRIPTION OF THE INVENTION

The principles, uses, and implementations of the teachings herein may be better understood with reference to the accompanying description and figures. Upon perusal of the description and figures present herein, one skilled in the art will be able to implement the teachings herein without undue effort or experimentation. In the figures, same reference numerals refer to same parts throughout.

As used herein, the term “backscattered scanning electron microscopy” or “BSEM” refers to measurement of backscattered electrons (BSEs) produced by scattering of a primary electron beam. When the primary beam hits the surface of a sample, the incident electrons can interact with the nuclei of the atoms and their trajectories are deviated. Typically, heavier elements, because of their bigger nuclei, can deflect incident electrons more strongly than lighter elements. Hence, heavy elements like silver, which has the atomic number Z=47, appear bright in a SEM image compared to light elements, such as silicon, that has atomic number Z=14, because more backscattered electrons are emitted from the sample surface.

As used herein, the terms “diffraction pattern” and “electron channeling patterns” may be used interchangeably and refer to a variation in signal resulting from changes in the angle between the incident beam and the crystal lattice of a specimen.

As used herein, the term Kikuchi lines refer to lines formed from diffraction patterns by backscattered electrons. The main features of their geometry can be deduced from both relative angle of electron beam tilt and crystal planes orientation, and electron beam energy.

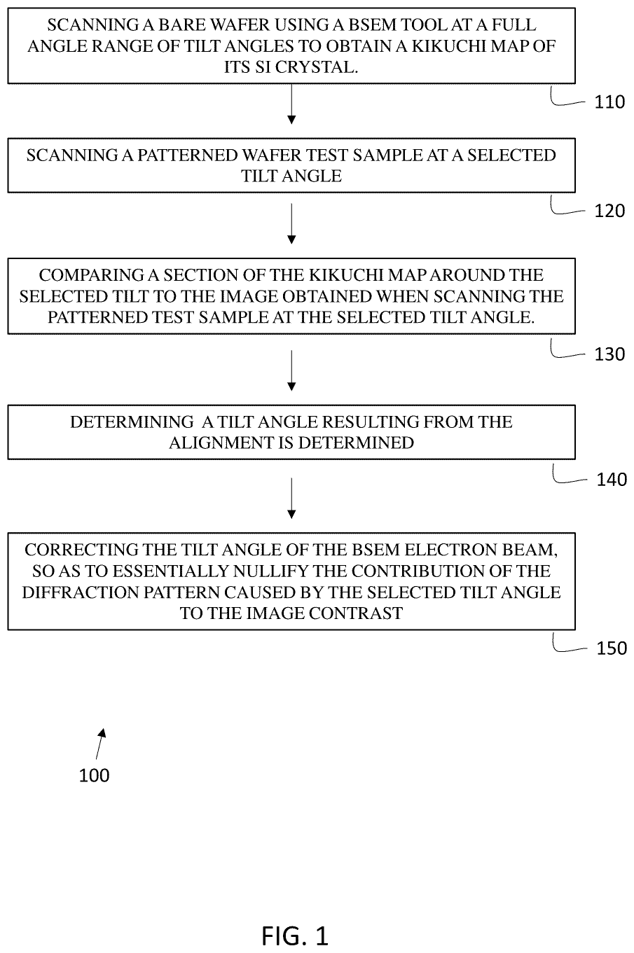

Reference is now made to FIG. 1, which shows a flowchart of the herein disclosed method 100 for calibration of BSEM electron beam angles, according to some embodiments.

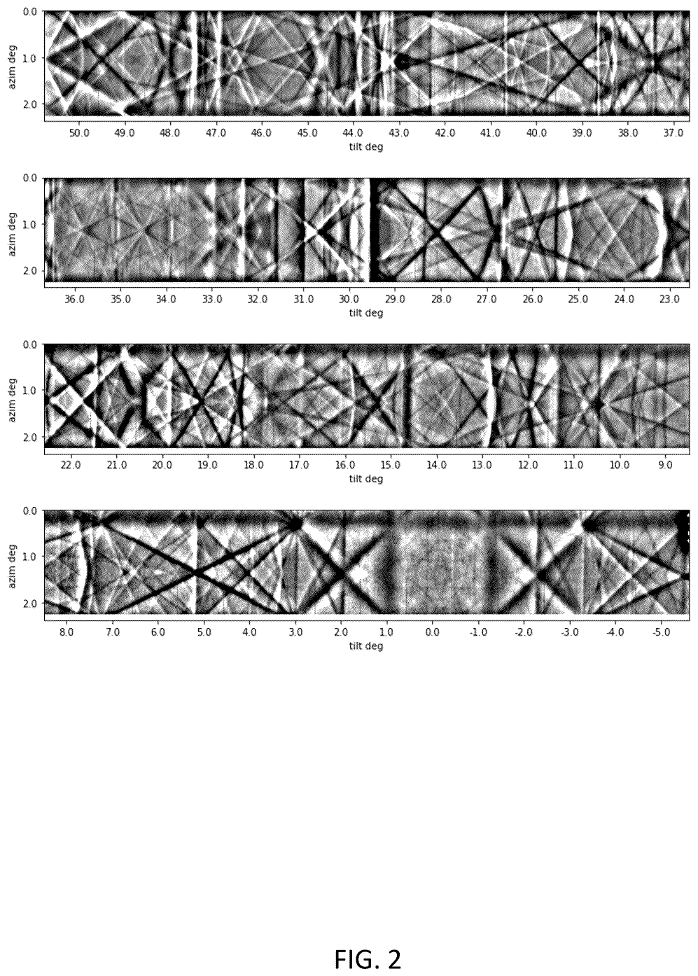

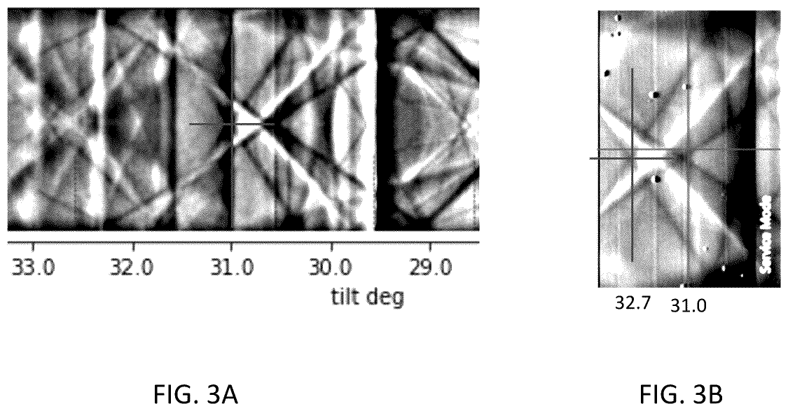

In step 110 a bare wafer is scanned using a BSEM tool at a full angle range of tilt angles and a Kikuchi map of its Si crystal is generated, as essentially shown in FIG. 2. Each image spans a variation of tilt of approximately 1 degree squared. A line map is obtained, and this map is used to translate patterns in Kikuchi lines and the angle of incident beam relative to crystal. The full map is composed of multiple SEM images (here 56) stitched together, where each image scans a range of approximately 1 degree in tilt and 2 degrees in azimuth. Here, the imaging mode was: 30 kev, 13 nA, pixel size 1.28 um, NA=1 mRad, however other imaging modes are also applicable and as such encompassed within this disclosure. Sample: bare Si wafer. Image was filtered to remove small frequencies and denoised. It is assumed that the crystal structures of all bare silicon wafers is essentially identical.

In step 120, a patterned wafer test sample is imaged at a selected tilt angle (here a tilt angle of 31 with 1 deg accuracy) at the same imaging mode used in step 110. The obtained scan is shown in FIG. 2B.

In step 130, a section of the Kikuchi map around the selected tilt angle (FIG. 2A) is compared to the image obtained when scanning the patterned test sample at the selected tilt angle. According to some embodiments, the comparison comprises aligning the test sample image with the section of the Kikuchi map, such that the position of the selected tilt angle (here tilt angle 31) are overlayed, i.e. the blue cross is aligned with the red cross.

In step 140, the tilt angle resulting from the alignment is determined (here, 32.7).

In step 150, the tilt angle of the BSEM electron beam is corrected by 1.7 degrees, so as to essentially nullify the contribution of the diffraction pattern caused by the selected tilt angle to the image contrast.

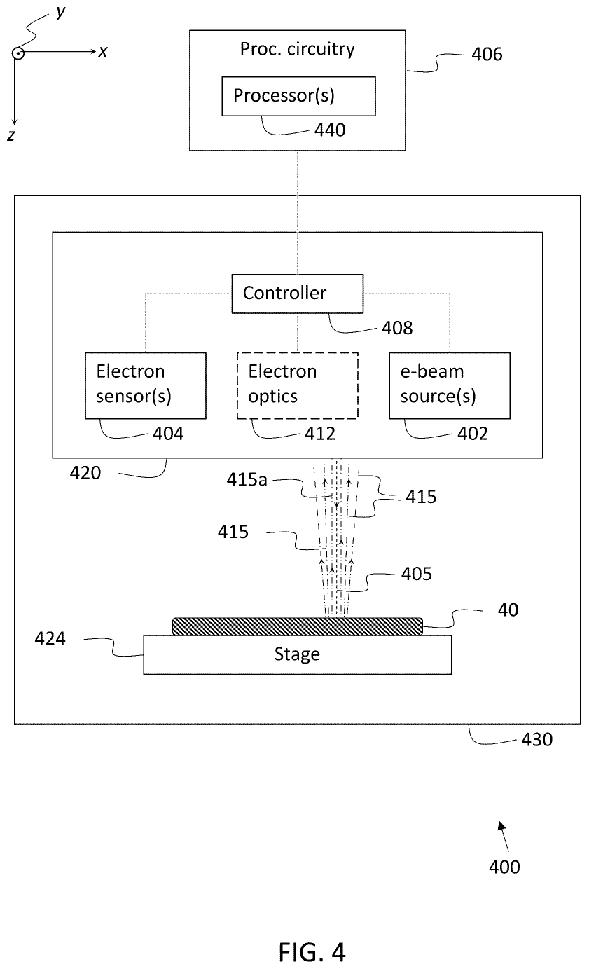

Reference is now made to FIG. 4, which depicts a computerized system 400 for calibration of tilt angles for depth-profiling of samples (e.g., patterned wafers and/or semiconductor structures therein or thereon). As will be apparent from the description thereof, system 400 may be used to implement method 100.

System 400 includes an e-beam source 402 (e.g., an electron gun), an electron sensor 404, processing circuitry 406 (also referred to as “computer hardware”), and a controller 408. According to some embodiments, system 400 may further include electron optics 412 configured to direct and/or focus an e-beam generated by e-beam source 402, and/or direct electrons (e.g., onto electron sensor 404) scattered from a sample due to the irradiation of the sample with the e-beam. According to some embodiments, and as depicted in FIG. 4, e-beam source 402, electron sensor 404, electron optics 412, and controller 408 may constitute components of a SEM 420. According to some embodiments, system 400 may further include a stage 424 (e.g., a xyz stage) configured to accommodate an (inspected) wafer 40. It is noted that wafer 40 does not form part of system 400.

Dotted lines between elements indicate functional or communicational association between the elements.

An e-beam 405, generated by e-beam source 402, is shown incident on sample 40. As a result of the tilt angle of e-beam 405 on sample 40, and the penetration of e-beam 405 into sample 40, backscattered electrons, as well as secondary electrons, are returned from wafer 40. Arrows 415 indicate backscattered electrons, as well as secondary electrons, which are scattered from sample 40 in the direction of electron sensor 404. According to some embodiments, electron sensor 404 may be configured to sense electrons returned at 180° relative to the incidence direction thereof of e-beam 405. An arrow 415a (from arrows 415) indicates electrons, which are returned at 180° relative to the incidence direction of e-beam 405.

According to some embodiments, electron sensor 404 is a BSE detector, i.e., being configured to sense backscattered electrons returned from wafer 40. According to some embodiments, electron sensor 404 may be a BSE image detector configured to obtain a BSE image. Electron sensor 404 is configured to relay the data collected thereby to processing circuitry 406 either directly, or, optionally (and as depicted in FIG. 4), indirectly via controller 408. According to some embodiments, in addition to electron sensor 404, system 400 may include an additional electron sensor (e.g., a second BSE detector).

According to some embodiments, electron optics 412 may include an electrostatic lens(es) and a magnetic deflector(s), which may be used to guide and manipulate an e-beam generated by e-beam source 402, and/or guide onto electron sensor 404 at least backscattered electrons generated due to the penetration of an e-beam into wafer 40.

According to some embodiments, electron optics 412 may include an energy filter (not shown) configured to transmit therethrough onto electron sensor 404 electrons having an energy above a threshold energy. More specifically, only electrons with energies higher than the energy threshold pass through the energy filter and reach electron sensor 404, thereby ensuring that substantially only electrons elastically scattered off matter in the sample are sensed by electron sensor 404.

According to some embodiments, SEM 420 and stage 424 may be housed within a vacuum chamber 430.

Controller 408 may be functionally associated with e-beam source 402 and, optionally, stage 424. More specifically, controller 408 is configured to control and synchronize operations and functions of the above-listed components of system 400.

Processing circuitry 406 includes one or more processors (i.e., processor(s) 440), and, optionally, RAM and/or non-volatile memory components (not shown). Processor(s) 440 is configured to execute software instructions stored in the non-volatile memory components. Through the execution of the software instructions, one or more measured sets of electron intensities (e.g., measured by electron sensor 404) of an inspected sample (e.g., wafer 40) are processed to for calibration of BSEM electron beam angles, as essentially described herein.

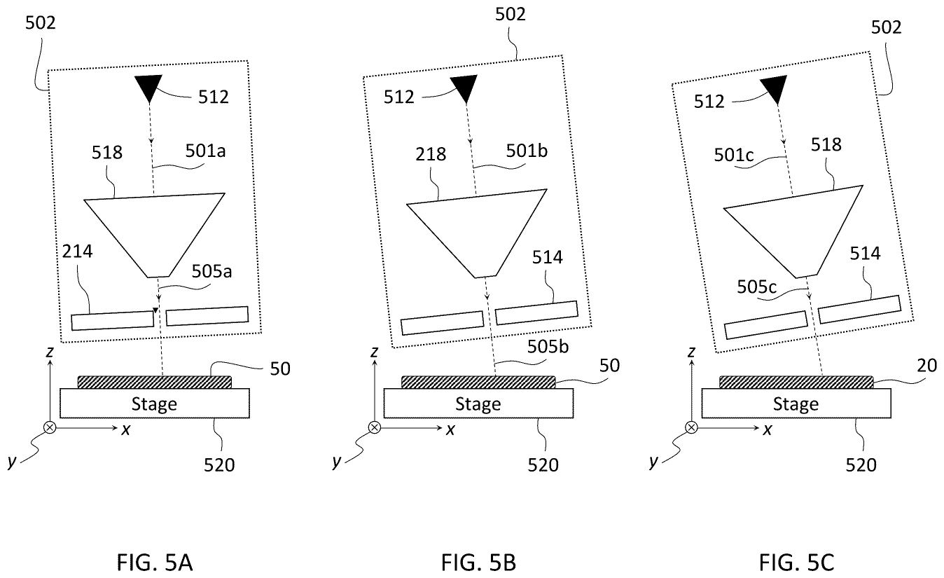

According to some embodiments, e-beam source 402 may be configured to allow projecting an e-beam at any one of a plurality of tilt angles and optionally a plurality of azimuth angles (as schematically illustrated in FIG. 5A-FIG. 5C) relative to sample 40, thereby allowing generation of a Kikuchi map as essentially disclosed herein.

According to some embodiments, electron sensor 404 (or one or more components thereof) may be laterally and/or vertically translatable, thereby allowing to control the collection angle (i.e., sense backscattered electrons returned from sample 40 at a desired return angle). According to some embodiments, backscattered electrons generated by e-beams of different landing energies may be sensed at different return angles, respectively.

According to some embodiments, electron sensor 404 may include a plurality of electron sensors, which are configured to sense backscattered electrons at each of plurality of return angles (equivalently, scattering angles). For example, a first electron sensor (e.g., a first BSE detector) may be positioned so as to measure backscattered electrons returned at a scattering angle of about 180°, while a second electron sensor (e.g. a second BSE detector) may be positioned so as to measure backscattered electrons returned at a scattering angle of about 170°, about 160°, or about 150°.

Reference is now made to FIG. 5A-FIG. 5C which schematically illustrate cross-sectional sideview of a wafer 50 being impinged by an e-beam 505a at a tilt angle θ1. Further shown are a SEM 502 and a stage 520 on which wafer 50 is placed. SEM 502 includes an electron gun 512, an electron sensor 514, a compound lens 518 configured to focus e-beam 505a on wafer 50, a scanner module (not shown) configured to offset e-beam 505a so as to enable scanning over a surface of a specimen, and, optionally, electron optics (not shown), such as magnetic deflectors, configured to controllably set the projection direction of e-beam 505a.

In operation, electron gun 512 produces an e-beam 501a, which impinges on wafer 50 at any of a plurality of tilt angles.

During calibration, and as described above with reference to method 100, a kikutchi map may be generated based on the scanning a bare wafer sample scanned at a plurality of tilt angles (preferably varying by approximately 1 degree), here illustrated tilt angles θ₁ (FIG. 5A), tilt angle θ₂ (θ₂>θ₁-FIG. 5B), and tilt angle θ₃ (θ₃>θ₂-FIG. 5C).

Once the map has been obtained, a patterned wafer may be scanned at a selected tilt angle and the obtained diffraction patterned can be compared to the diffraction pattern obtained from scanning the bare wafer at the selected tilt angle as well as the selected tilt angle ±1 degree.

Based on the alignment of the patterns, the tilt angle of e-beam 501a produced by electron gun 512 may be adjusted thereby reducing the impact that the diffraction adds to the material contrast when scanning a patterned wafer.

In the description and claims of the application, the words “include” and “have”, and forms thereof, are not limited to members in a list with which the words may be associated.

As used herein, the term “substantially” may be used to specify that a first property, quantity, or parameter is close or equal to a second or a target property, quantity, or parameter. For example, a first object and a second object may be said to be of “substantially the same length”, when a length of the first object measures at least 80% (or some other pre-defined threshold percentage) and no more than 120% (or some other pre-defined threshold percentage) of a length of the second object. In particular, the case wherein the first object is of the same length as the second object is also encompassed by the statement that the first object and the second object are of “substantially the same length”.

As used herein, the term “about” may be used to specify a value of a quantity or parameter (e.g. the length of an element) to within a continuous range of values in the neighborhood of (and including) a given (stated) value. According to some embodiments, “about” may specify the value of a parameter to be between 80% and 120% of the given value. For example, the statement “the length of the element is equal to about 1 m” is equivalent to the statement “the length of the element is between 0.8 m and 1.2 m”. According to some embodiments, “about” may specify the value of a parameter to be between 90% and 110% of the given value. According to some embodiments, “about” may specify the value of a parameter to be between 95% and 105% of the given value.

As used herein, according to some embodiments, the terms “substantially” and “about” may be interchangeable.

It is appreciated that certain features of the disclosure, which are, for clarity, described in the context of separate embodiments, may also be provided in combination in a single embodiment. Conversely, various features of the disclosure, which are, for brevity, described in the context of a single embodiment, may also be provided separately or in any suitable sub-combination or as suitable in any other described embodiment of the disclosure. No feature described in the context of an embodiment is to be considered an essential feature of that embodiment, unless explicitly specified as such.

Although operations in disclosed methods, according to some embodiments, may be described in a specific sequence, methods of the disclosure may include some or all of the described operations carried out in a different order. A method of the disclosure may include a few of the operations described or all of the operations described. No particular operation in a disclosed method is to be considered an essential operation of that method, unless explicitly specified as such.

Although the disclosure is described in conjunction with specific embodiments thereof, it is evident that numerous alternatives, modifications and variations that are apparent to those skilled in the art may exist. Accordingly, the disclosure embraces all such alternatives, modifications and variations that fall within the scope of the appended claims. It is to be understood that the disclosure is not necessarily limited in its application to the details of construction and the arrangement of the components and/or methods set forth herein. Other embodiments may be practiced, and an embodiment may be carried out in various ways.

The phraseology and terminology employed herein are for descriptive purpose and should not be regarded as limiting. Citation or identification of any reference in this application shall not be construed as an admission that such reference is available as prior art to the disclosure. Section headings are used herein to ease understanding of the specification and should not be construed as necessarily limiting.

What is claimed is:

1. A method for calibrating a tilt angle of an electron beam of a backscattered scanning electron microscope (BSEM) tool, the method comprising:
scanning a bare wafer, utilizing the BSEM tool, at a plurality of electron beam tilt and azimuth angles, such that each image obtained spans a different tilt angle or range thereof at a predetermined range of azimuth angles, thereby obtaining a calibration map representing a crystal orientation of the bare wafer;
selecting a tilt angle and defining an expected diffraction pattern associated with the tilt angle, based on the calibration map;
scanning a patterned wafer at the selected tilt angle, utilizing the BSEM tool;
comparing the diffraction pattern of the image obtained from the scanning of the patterned wafer at the selected tilt angle with the expected diffraction pattern; and
correcting the tilt angle of the electron beam of the BSEM tool, such that the diffraction pattern of the image obtained during scanning of the patterned wafer will align with the expected diffraction pattern.

2. The method of claim 1 further comprising scanning one or more additional patterned wafers at the corrected tilt angle

3. The method of claim 1, wherein the plurality of tilt angle varies by approximately 1 degree, between scans.

4. The method of claim 1, wherein the predetermined range of azimuth angles is approximately 2 degrees.

5. The method of claim 1, wherein the tilt angle range around the desired tilt angle comprises the selected tilt angle±about 2-5 degrees.

6. The method of claim 1, wherein the comparing and correcting comprises superimposing the image obtained during scanning of the patterned wafer at the selected tilt angle on the image obtained during scanning of the bare wafer such that the diffraction pattern obtained during scanning of the patterned wafer aligns with the expected diffraction pattern.

7. The method of claim 1 further comprising conducting a metrology analysis of the obtained patterned wafer images.

8. The method of claim 1, wherein the calibration map is a Kikuchi map.

9. A method for improved scanning of a patterned wafer with a backscattered scanning electron microscope (BSEM) tool, the method comprising:
scanning a patterned wafer at a selected tilt angle, thereby obtaining a diffraction pattern;
comparing the diffraction pattern with an image having an expected diffraction pattern; wherein the expected diffraction pattern is a diffraction pattern obtained when scanning a bare wafer at the selected tilt angle; and
correcting the tilt angle of the electron beam of the BSEM tool, such that the diffraction pattern of the image obtained during scanning of the patterned wafer aligns with the expected diffraction pattern.

10. The method of claim 9 further comprising scanning one or more additional patterned wafers at the corrected tilt angle.

11. The method of claim 9, wherein the comparing and correcting comprises superimposing the image obtained during scanning of the patterned wafer at the selected tilt angle on the image obtained during scanning of the bare wafer such that the diffraction pattern obtained during scanning of the patterned wafer aligns with the expected diffraction pattern.

12. The method of claim 9, further comprising conducting a metrology analysis of the obtained patterned wafer images.

13. A system for calibrating a tilt angle of an electron beam of a backscattered scanning electron microscope (BSEM) tool for optimization of diffraction angles, the BSEM tool is configured to:
scan a bare wafer at a plurality of electron beam tilt angles and azimuth angles, thereby obtaining a plurality of images, each spanning a different tilt angle or range thereof at a predetermined range of azimuth angles, and
scan a patterned wafer, utilizing the BSEM tool, at selected tilt angle range; and
wherein the system for calibrating a tilt angle of an electron beam of a the BSEM tool comprises:
a processing unit configured to:
receive the plurality of images obtained during scanning of the bare wafer;
generate a calibration map representing the crystal structure of the bare wafer;
select a tilt angle and defining an expected diffraction pattern associated with the tilt angle, based on the calibration map;
obtain the image from the scanning of the patterned wafer at the selected tilt angle;
compare the diffraction pattern of the image of the patterned wafer with the expected diffraction pattern;
determine a corrected tilt angle suitable for scanning the patterned wafer, wherein the determining comprises aligning the diffraction pattern of the patterned wafer with the expected diffraction pattern, and
instruct the BSEM tool to change the tilt angle of the electron beam to the corrected tilt angle.

14. The system of claim 13, wherein the BSEM tool is further configured to scan additional patterned wafers at the corrected tilt angle.

15. The system of claim 13, wherein the processing unit is further configured to conduct a metrology analysis of the additional patterned wafers, based on the scans thereof at the corrected tilt angle.
